(19) United States
(12) Patent Application Publication
(10) Pub. No.: US 2015/0369965 A1
(43) Pub. Date: Dec. 24, 2015

(54) ANTI-REFLECTION FILM AND PRODUCTION METHOD THEREFOR

(71) Applicant: NITTO DENKO CORPORATION, Ibaraki-shi, Osaka (JP)

(72) Inventors: Atsushi Kishi, Ibaraki-shi (JP); Tomonori Ueno, Ibaraki-shi (JP); Hiroki Kuramoto, Ibaraki-shi (JP)

(73) Assignee: NITTO DENKO CORPORATION, Ibaraki-shi, Osaka (JP)

(21) Appl. No.: 14/763,573

(22) PCT Filed: Jan. 27, 2014
(86) PCT No.: PCT/JP2014/051655

§ 371 Date: Jul. 27, 2015

(30) Foreign Application Priority Data
Jan. 29, 2013 (JP) 2013-014458

(51) Int. Cl. G02B 1/11; C23C 14/34; G02B 5/30

(52) U.S. Cl. CPC G02B 1/11; G02B 5/3033; C23C 14/34

(57) ABSTRACT

An anti-reflection film according to the present invention includes: a substrate; and a medium-refractive index layer, a high-refractive index layer, and a low-refractive index layer in the stated order from a substrate side, wherein: the substrate has a refractive index ranging from 1.45 to 1.65; the medium-refractive index layer is formed by applying, onto the substrate, a composition for forming a medium-refractive index layer containing a binder resin and inorganic fine particles, and curing the composition, has a refractive index ranging from 1.67 to 1.78, and has a thickness of from 70 nm to 120 nm; the high-refractive index layer has a refractive index ranging from 2.00 to 2.60, and has a thickness of from 10 nm to 25 nm; and the low-refractive index layer has a refractive index ranging from 1.35 to 1.55, and has a thickness of from 70 nm to 120 nm.

### TECHNICAL FIELD

The present invention relates to an anti-reflection film and a method of producing the film. More specifically, the present invention relates to a method of producing an anti-reflection film including a dry process and a wet process, and an anti-reflection film to be obtained by the production method.

### BACKGROUND ART

An anti-reflection film to be placed on the surface of the display screen of, for example, a CRT, a liquid crystal display apparatus, or a plasma display panel has heretofore been widely used for preventing the reflection of ambient light on the display screen. As the anti-reflection film, there has been known, for example, a multilayer film having a layer formed of a medium-refractive index material, a layer formed of a high-refractive index material, and a layer formed of a low-refractive index material. It has been known that the use of such multilayer film can provide high anti-reflection performance (a low reflectance in a wide spectrum). Such multilayer film is generally formed by a dry process such as a vapor deposition method or a sputtering method. However, the dry process involves a problem in that the process is poor in productivity and hence leads to an increase in production cost.

To solve the problem, a multilayer anti-reflection film obtained by combining the dry process and a wet process such as coating or application has been proposed (for example, Patent Literature 1). However, the productivity and cost-reducing effect of each of technologies proposed heretofore including Patent Literature 1 are still insufficient, and the optical characteristics of anti-reflection films to be obtained by employing the technologies are also insufficient.

Incidentally, the anti-reflection performance of an anti-reflection film is generally evaluated in terms of a luminous reflectance Y (%), and as the luminous reflectance reduces, the anti-reflection performance becomes more excellent. However, when an attempt is made to reduce the luminous reflectance, there arises a problem in that the reflection hue of the film is liable to color.

As described above, a multilayer anti-reflection film that achieves compatibility between a low luminous reflectance and a reflection hue that colors to a small extent and is close to neutral, and a technology by which such film can be obtained with high productivity and at a low cost have been strongly desired.

### CITATION LIST

### Patent Literature

[PTL 1] JP 2002-243906 A

### SUMMARY OF INVENTION

### Technical Problem

The present invention has been made to solve the conventional problems, and an object of the present invention is to provide an anti-reflection film having an excellent reflection characteristic (low reflectivity) in a wide spectrum, an excellent reflection hue that is close to neutral and, in addition, having an excellent mechanical characteristic, and a method of manufacturing such anti-reflection film with high productivity and at a low cost.

### Solution to Problem

An anti-reflection film according to the present invention includes: a substrate; and a medium-refractive index layer, a high-refractive index layer, and a low-refractive index layer in the stated order from a substrate side, wherein: the substrate has a refractive index ranging from 1.45 to 1.65; the medium-refractive index layer is formed by applying, onto the substrate, a composition for forming a medium-refractive index layer containing a binder resin and inorganic fine particles, and curing the composition, has a refractive index ranging from 1.67 to 1.78, and has a thickness of from 70 nm to 120 nm; the high-refractive index layer has a refractive index ranging from 2.00 to 2.60, and has a thickness of from 10 nm to 25 nm; and the low-refractive index layer has a refractive index ranging from 1.35 to 1.55, and has a thickness of from 70 nm to 120 nm.

In one embodiment of the present invention, the thickness of the high-refractive index layer is from 10 nm to 20 nm.

In one embodiment of the present invention, the high-refractive index layer is formed by sputtering a metal oxide or a metal nitride, or by sputtering a metal while introducing oxygen to oxidize the metal.

In one embodiment of the present invention, the binder resin includes an ionizing radiation-curable resin, and the inorganic fine particles include zirconia particles or titanium oxide particles each having a particle diameter of from 1 nm to 100 nm.

According to another aspect of the present invention, there is provided a method of producing an anti-reflection film. The method of producing an anti-reflection film includes: applying, onto a substrate, a composition for forming a medium-refractive index layer containing a binder resin and inorganic fine particles, followed by curing of the composition to form a medium-refractive index layer; sputtering a metal oxide or a metal nitride onto the medium-refractive index layer, or sputtering a metal onto the medium-refractive index layer while introducing oxygen to oxidize the metal, to form a high-refractive index layer; and sputtering a metal oxide or a metal fluoride onto the high-refractive index layer to form a low-refractive index layer, the substrate having a refractive index ranging from 1.45 to 1.65; the medium-refractive index layer having a refractive index ranging from 1.67 to 1.78, and having a thickness of from 70 nm to 120 nm, the high-refractive index layer having a refractive index ranging from 2.00 to 2.60, and having a thickness of from 10 nm to 25 nm, the low-refractive index layer having a refractive index ranging from 1.35 to 1.55, and having a thickness of from 70 nm to 120 nm.

According to still another aspect of the present invention, there is provided a polarizing plate with an anti-reflection film. The polarizing plate with an anti-reflection film includes the anti-reflection film as described above.

According to still another aspect of the present invention, there is provided an image display apparatus. The image display apparatus includes the anti-reflection film as described above or the polarizing plate with an anti-reflection film as described above.

### Advantageous Effects of Invention

According to the embodiment of the present invention, the anti-reflection film can be obtained with high productivity and at a low cost by employing a wet process in the formation of the medium-refractive index layer, and by markedly reducing the thickness of the high-refractive index layer as compared to a conventional one. In addition, according to the embodiment of the present invention, the anti-reflection film having an excellent reflection characteristic (low reflectivity) in a wide spectrum, an excellent reflection hue that is close to neutral and, in addition, having an excellent mechanical characteristic can be obtained by optimizing the refractive index and thickness of each layer.

### BRIEF DESCRIPTION OF DRAWINGS

FIG. 1 is a schematic sectional view of an anti-reflection film according to one embodiment of the present invention.

### DESCRIPTION OF EMBODIMENTS

Hereinafter, preferred embodiments of the present invention are described with reference to the drawings, but the present invention is not limited to these embodiments. It should be noted that the lengths, thicknesses, and the like of the respective layers and the like in the drawings are different from actual scales for ease of viewing.

A. Entire Construction of Anti-Reflection Film

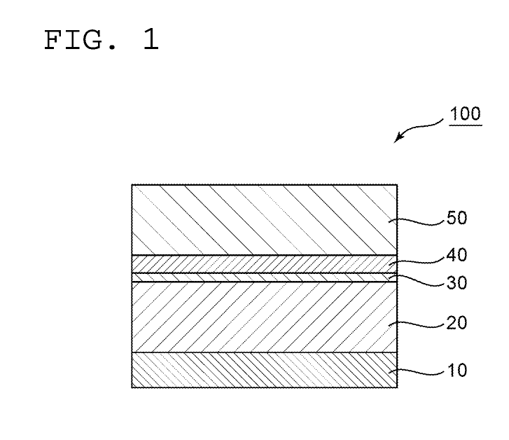

FIG. 1 is a schematic sectional view of an anti-reflection film according to one embodiment of the present invention. An anti-reflection film 100 includes a substrate 10, and a medium-refractive index layer 20, an adhesion layer 30 to be arranged as required, a high-refractive index layer 40, and a low-refractive index layer 50 in the stated order from the substrate 10 side. The substrate has a refractive index nₛ ranging from 1.45 to 1.65. The medium-refractive index layer is formed by applying, onto the substrate, a composition for forming a medium-refractive index layer containing a binder resin and inorganic fine particles, and curing the composition. The medium-refractive index layer has a refractive index n_{M} ranging from 1.67 to 1.78, and has a thickness of from 70 nm to 120 nm. The high-refractive index layer has a refractive index n_{H} ranging from 2.00 to 2.60, and has a thickness of from 10 nm to 25 nm. The low-refractive index layer has a refractive index n_{L} ranging from 1.35 to 1.55, and has a thickness of from 70 nm to 120 nm. In the present invention, the thickness of the high-refractive index layer is markedly reduced as compared to a conventional one. The high-refractive index layer is typically formed by the sputtering of a metal oxide such as Nb₂O₅, but the rate of such sputtering is known to be extremely slow. Therefore, the production efficiency of the entirety of the anti-reflection film can be significantly improved by reducing the thickness of the high-refractive index layer. Further, the production efficiency can be additionally improved and a production cost for the film can be additionally reduced by forming the medium-refractive index layer according to a wet process. As a result, according to the present invention, the anti-reflection film can be obtained with high productivity and at a low cost. In addition, according to the present invention, an anti-reflection film having excellent reflection performance (low reflectivity) in a wide spectrum can be obtained by optimizing the refractive index and thickness of each layer.

In one embodiment, the anti-reflection film 100 is such that the refractive index nₛ of the substrate, the refractive index n_{M} of the medium-refractive index layer, and the refractive index n_{H} of the high-refractive index layer satisfy the following expression (1). In the expression (1), the refractive index nₛ of the substrate, the refractive index n_{M} of the medium-refractive index layer, and the refractive index n_{H} of the high-refractive index layer have a relationship of n_{H}>n_{M}>nₛ.

$$\frac{{n}_{H} - 1}{{n}_{H} + 1} - \sqrt{1 - \frac{4 {n}_{M}^{2} {n}_{s}}{{{n}_{M}^{2} ( 1 + {n}_{S} )}^{2} - ( 1 - {n}_{M}^{2} ) ( {n}_{M}^{2} - {n}_{S}^{2} )}} ≧ 0.02 \qquad ( 1 )$$

In the expression (1), when (n_{H}−1)/(n_{H}+1) on the left of the left side is represented by R₁ and the expression represented by a square root on the right of the left side is represented by R₂, R₁ means a reflectance intrinsic to the high-refractive index layer and R₂ means a reflectance when the medium-refractive index layer having an optical thickness of λ/4 is laminated on the substrate. As a difference (R₁−R₂) enlarges, a desired reflectance can be obtained better while the thickness of the high-refractive index layer is reduced. Therefore, in the present invention, the difference (R₁−R₂) is preferably 0.02 or more, more preferably 0.03 or more. An upper limit for the difference (R₁−R₂) is, for example, 0.2.

The reflection hue of the anti-reflection film in the CIE-Lab colorimetric system is as follows: relationships of 0≦a*≦15 and −20≦b*≦0 are preferably satisfied, and relationships of 0≦a*≦10 and −15b*≦0 are more preferably satisfied. According to the present invention, the optimization of the refractive indices and thicknesses of the respective layers can provide an anti-reflection film having an excellent reflection hue that is close to neutral in addition to the above-mentioned effect.

The luminous reflectance Y of the anti-reflection film is preferably as low as possible, and is preferably 1.0% or less, more preferably 0.7% or less, still more preferably 0.5% or less. As described above, according to the present invention, compatibility between a low luminous reflectance (an excellent anti-reflection characteristic) and a reflection hue that colors to a small extent and is close to neutral (an excellent reflection hue) can be achieved in a multilayer anti-reflection film.

Hereinafter, each layer constituting the anti-reflection film is described in detail.

A-1. Substrate

The substrate 10 can be constituted of any appropriate resin film as long as the effects of the present invention are obtained. Specifically, the substrate 10 can be a resin film having transparency. Specific examples of the resin for forming the film include polyolefin-based resins (such as polyethylene and polypropylene), polyester-based resins (such as polyethylene terephthalate and polyethylene naphthalate), polyamide-based resins (such as nylon-6 and nylon-66), a polystyrene resin, a polyvinyl chloride resin, a polyimide resin, a polyvinyl alcohol resin, an ethylene vinyl alcohol resin, a (meth)acrylic resin, a (meth)acrylonitrile resin, and cellulose-based resins (such as triacetylcellulose, diacetylcellulose, and cellophane). The substrate may be a single layer, may be a laminate of a plurality of resin films, or may be a laminate of a resin film (a single layer or a laminate) and the following hard coat layer. The substrate (substantially a composition for forming the substrate) can contain any appropriate additive. Specific examples of the additive include an antistatic agent, a UV-absorbing agent, a plasticizer, a lubricant, a colorant, an antioxidant, and a flame retardant. It should be noted that detailed description of a material constituting the substrate is omitted because the material is well known in the art.

In one embodiment, the substrate 10 can function as a hard coat layer. That is, as described above, the substrate 10 may be a laminate of a resin film (a single layer or a laminate) and a hard coat layer to be described below. Alternatively, the hard coat layer may constitute the substrate alone. When the substrate is constituted of the laminate of the resin film and the hard coat layer, the hard coat layer can be placed so as to be adjacent to the medium-refractive index layer 20. The hard coat layer is a cured layer of any appropriate ionizing radiation-curable resin. Examples of an ionizing radiation include UV light, visible light, an infrared ray, and an electron beam. Of those, UV light is preferred. Therefore, the ionizing radiation-curable resin is preferably a UV-curable resin. Examples of the UV-curable resin include a (meth)acrylic resin, a silicone-based resin, a polyester-based resin, a urethane-based resin, an amide-based resin, and an epoxy-based resin. A typical example of the (meth)acrylic resin is a cured product (polymerized product) obtained by curing a (meth)acryloyloxy group-containing polyfunctional monomer with a UV light. The polyfunctional monomers may be used alone or in combination. Any appropriate photopolymerization initiator can be added to the polyfunctional monomer. It should be noted that detailed description of a material constituting the hard coat layer is omitted because the material is well known in the art.

Any appropriate inorganic or organic fine particles can be dispersed in the hard coat layer. The particle diameter of each of the fine particles is, for example, from 0.01 μm to 3 μm. Alternatively, an uneven shape can be formed on the surface of the hard coat layer. The adoption of such construction can impart a light-diffusing function generally referred to as “antiglare”. Silicon oxide (SiO₂) can be suitably used as the fine particles to be dispersed in the hard coat layer from the viewpoints of, for example, a refractive index, stability, and heat resistance. Further, the hard coat layer (substantially a composition for forming the hard coat layer) can contain any appropriate additive. Specific examples of the additive include a leveling agent, a filler, a dispersant, a plasticizer, a UV-absorbing agent, a surfactant, an antioxidant, and a thixotropic agent.

The hard coat layer has a hardness of preferably H or more, more preferably 3H or more in a pencil hardness test. The measurement of the pencil hardness test maybe performed in conformity with JIS K 5400.

The thickness of the substrate 10 can be appropriately set depending on, for example, a purpose and the construction of the substrate. When the substrate is constituted as a single layer of a resin film or a laminate of resin films, the thickness is, for example, from 10 μm to 200 μm. When the substrate includes a hard coat layer or when the substrate is constituted of the hard coat layer alone, the thickness of the hard coat layer is, for example, from 1 μm to 50 μm.

The refractive index of the substrate 10 (when the substrate has a laminated structure, the refractive index of a layer adjacent to the medium-refractive index layer) is preferably from 1.45 to 1.65, more preferably from 1.50 to 1.60. Such refractive index can increase a degree of freedom in design of the medium-refractive index layer formed by a wet process. It should be noted that the term “refractive index” as used herein refers to a refractive index measured at a temperature of 25° C. and a wavelength A of 580 nm on the basis of JIS K 7105 unless otherwise stated.

A-2. Medium-Refractive Index Layer

The medium-refractive index layer 20 typically contains a binder resin and inorganic fine particles dispersed in the binder resin. The binder resin is typically an ionizing radiation-curable resin, more specifically a UV-curable resin. Examples of the UV-curable resin include radical-polymerizable monomers and oligomers such as a (meth)acrylate resin (epoxy (meth)acrylate, polyester (meth)acrylate, acrylic (meth)acrylate, or ether (meth)acrylate). A monomer component (precursor) that constructs the acrylate resin preferably has a molecular weight of from 200 to 700. Specific examples of the monomer component (precursor) that constructs the (meth)acrylate resin include pentaerythritol triacrylate (PETA, molecular weight: 298), neopentylglycol diacrylate (NPGDA, molecular weight: 212), dipentaerythritol hexaacrylate (DPHA, molecular weight: 632), dipentaerythritol pentaacrylate (DPPA, molecular weight: 578), and trimethylolpropane triacrylate (TMPTA, molecular weight: 296). If required, an initiator may be added. Examples of the initiator include a UV radical generator (e.g., Irgacure 907, 127, or 192 manufactured by Ciba Specialty Chemicals) and benzoyl peroxide. The binder resin may contain another resin component other than the above-mentioned ionizing radiation-curable resin. The another resin component may be an ionizing radiation-curable resin, a thermosetting resin, or a thermoplastic resin. Typical examples of the another resin component include an aliphatic (for example, polyolefin) resin and a urethane-based resin. In the case of using the another resin component, the kind and blending amount thereof are adjusted so that the refractive index of the medium-refractive index layer to be obtained satisfies the relationship of the above-mentioned expression (1).

The refractive index of the binder resin is preferably from 1.40 to 1.60.

The blending amount of the binder resin is preferably from 10 parts by weight to 80 parts by weight, more preferably from 20 parts by weight to 70 parts by weight with respect to 100 parts by weight of the medium-refractive index layer to be formed.

The inorganic fine particles maybe constituted of, for example, a metal oxide. Specific examples of the metal oxide include zirconium oxide (zirconia) (refractive index: 2.19), aluminum oxide (refractive index: 1.56 to 2.62), titanium oxide (refractive index: 2.49 to 2.74), and silicon oxide (refractive index: 1.25 to 1.46). Each of those metal oxides absorbs a small quantity of light and has a refractive index that is hardly expressed by an organic compound such as an ionizing radiation-curable resin or a thermoplastic resin. Accordingly, the refractive index of the medium-refractive index layer can be easily adjusted, and as a result, a medium-refractive index layer having a refractive index within the desired range described above can be formed by coating. Particularly preferred inorganic compounds are zirconium oxide and titanium oxide. This is because each of zirconium oxide and titanium oxide has an appropriate refractive index and appropriate dispersibility in the binder resin, and hence can form a medium-refractive index layer having a desired refractive index and a desired dispersed structure.

The refractive index of the inorganic fine particles is preferably 1.60 or more, more preferably from 1.70 to 2.80, particularly preferably from 2.00 to 2.80. When the refractive index falls within such range, a medium-refractive index layer having a desired refractive index can be formed. When the blending amount of the inorganic fine particles is excessively large, the mechanical characteristics of an anti-reflection film to be obtained become insufficient in some cases. In addition, in terms of optical design, the thickness of the high-refractive index layer needs to be increased and hence the productivity of the anti-reflection film becomes insufficient in many cases. When the blending amount is excessively small, a desired luminous reflectance is not obtained in some cases.

The average particle diameter of the inorganic fine particles is preferably from 1 nm to 100 nm, more preferably from 10 nm to 80 nm, still more preferably from 20 nm to 70 nm. As described above, by using the inorganic fine particles with an average particle diameter smaller than the wavelength of light, geometric reflection, refraction, and scattering are not caused between the inorganic fine particles and the binder resin, and a medium-refractive index layer that is optically uniform can be obtained.

It is preferred that the inorganic fine particles has satisfactory dispersibility with the binder resin. The term “satisfactory dispersibility” as used herein means that a coating film, which is obtained by applying an application liquid obtained by mixing the binder resin, the inorganic fine particles (if required, a small amount of a UV initiator), and a volatile solvent, followed by removing the solvent by drying, is transparent.

In one embodiment, the inorganic fine particles are subjected to surface modification. By conducting surface modification, the inorganic fine particles can be dispersed satisfactorily in the binder resin. As surface modification means, any suitable means can be adopted as long as the effect of the present invention is obtained. Typically, the surface modification is conducted by applying a surface modifier onto the surface of each of the inorganic fine particles to form a surface modifier layer. Specific examples of the preferred surface modifier include coupling agents such as a silane-based coupling agent and a titanate-based coupling agent, and a surfactant such as a fatty acid-based surfactant. By using such surface modifier, the wettability between the binder resin and the inorganic fine particles can be enhanced, the interface between the binder resin and the inorganic fine particles can be stabilized, and the inorganic fine particles can be dispersed satisfactorily in the binder resin. In another embodiment, the inorganic fine particles can be used without being subjected to any surface modification.

The blending amount of the inorganic fine particles is preferably from 10 parts by weight to 90 parts by weight, more preferably from 20 parts by weight to 80 parts by weight with respect to 100 parts by weight of the medium-refractive index layer to be formed.

The thickness of the medium-refractive index layer 20 is preferably from 70 nm to 120 nm, more preferably from 80 nm to 115 nm. Such thickness can realize a desired optical thickness.

The refractive index of the medium-refractive index layer 20 is preferably from 1.67 to 1.78, more preferably from 1.70 to 1.78. When an attempt is made to realize low reflectivity in a wide spectrum in a conventional anti-reflection film, in the case where the refractive index of the low-refractive index layer is 1.47 and the refractive index of the high-refractive index layer is 2.33, the refractive index of the medium-refractive index layer has needed to be set to around 1.9. However, according to the present invention, even such low refractive index can realize desired optical characteristics. As a result, the medium-refractive index layer can be formed by the application and curing of a resin-based composition whose refractive index cannot be increased to a very large extent from the viewpoint of a mechanical characteristic (hardness), which can largely contribute to an improvement in productivity and a cost reduction.

The optical thickness of the medium-refractive index layer 20 at a wavelength of 580 nm is about λ/4 in order that the medium-refractive index layer may have a reflection-lowering function. It should be noted that the optical thickness is the product of a refractive index n and a thickness d, and is represented as a ratio with respect to a wavelength of interest (here, 580 nm).

A-3. Adhesion Layer

The adhesion layer 30 is an optional layer that can be arranged for improving adhesiveness between the medium-refractive index layer 20 and the high-refractive index layer 40. The adhesion layer can be constituted of, for example, silicon. The thickness of the adhesion layer is, for example, from 2 nm to 5 nm.

A-4. High-Refractive Index Layer

When the high-refractive index layer 40 is used in combination with the low-refractive index layer 50, the anti-reflection film can efficiently prevent the reflection of light by virtue of a difference between their respective refractive indices. The high-refractive index layer 40 can be preferably placed so as to be adjacent to the low-refractive index layer 50. Further, the high-refractive index layer 40 can be preferably placed on the substrate side of the low-refractive index layer 50. Such construction can prevent the reflection of light in an extremely efficient manner.

The thickness of the high-refractive index layer 40 is, as described above, preferably from 10 nm to 25 nm, more preferably from 10 nm to 20 nm, still more preferably from 12 nm to 18 nm. According to the present invention, the thickness of the high-refractive index layer can be markedly reduced as compared with the conventional one by forming such a specific medium-refractive index layer as described in the section A-2. As a result, an anti-reflection film having desired reflection performance can be obtained with high productivity and at a low cost. When the thickness of the high-refractive index layer is excluded from the range as described above, a reflection hue having undesired color can be achieved in many cases.

The refractive index of the high-refractive index layer 40 is preferably from 2.00 to 2.60, more preferably from 2.10 to 2.45. With such refractive index, a desired refractive index difference between the high-refractive index layer and the low-refractive index layer can be secured, and hence the reflection of light can be efficiently prevented.

The optical thickness of the high-refractive index layer 40 at a wavelength of 580 nm is preferably λ/8 or less, more preferably approximately from λ/32 to λ/8. As described above, according to the present invention, the thickness of the high-refractive index layer can be markedly reduced as compared with the conventional one, and as a result, its optical thickness can also be markedly reduced. In addition, even such small optical thickness can secure desired reflection performance.

Any appropriate material can be used as a material constituting the high-refractive index layer 40 as long as the desired characteristics are obtained. Typical examples of such material include a metal oxide and a metal nitride. Specific examples of the metal oxide include titanium oxide (TiO₂), indium/tin oxide (ITO), niobium oxide (Nb₂O₅), yttrium oxide (Y₂O₃), indium oxide (In₂O₃), tin oxide (SnO₂), zirconium oxide (ZrO₂), hafnium oxide (HfO₂), antimony oxide (Sb₂O₃), tantalum oxide (Ta₂O₅), zinc oxide (ZnO), and tungsten oxide (WO₃). A specific example of the metal nitride is silicon nitride (Si₃N₄). Of those, niobium oxide (Nb₂O₅) or titanium oxide (TiO₂) is preferred. This is because Nb₂O₅ or TiO₂ has an appropriate refractive index and a low sputtering rate, and thus, the thinner film formation effect of the present invention becomes significant.

A-5. Low-Refractive Index Layer

As described above, when the low-refractive index layer 50 is used in combination with the high-refractive index layer 40, the anti-reflection film can efficiently prevent the reflection of light by virtue of the difference between their respective refractive indices. The low-refractive index layer 50 can be preferably placed so as to be adjacent to the high-refractive index layer 40. Further, the low-refractive index layer 50 can be preferably placed on the side of the high-refractive index layer 40 opposite to the substrate. Such construction can prevent the reflection of light in an extremely efficient manner.

The thickness of the low-refractive index layer 50 is preferably from 70 nm to 120 nm, more preferably from 80 nm to 115 nm. Such thickness can realize a desired optical thickness.

The refractive index of the low-refractive index layer 50 is preferably from 1.35 to 1.55, more preferably from 1.40 to 1.50. With such refractive index, a desired refractive index difference between the low-refractive index layer and the high-refractive index layer can be secured, and hence the reflection of light can be efficiently prevented.

The optical thickness of the low-refractive index layer 50 at a wavelength of 580 nm is about λ/4 because the layer corresponds to a general low-reflection layer.

Any appropriate material can be used as a material constituting the low-refractive index layer 50 as long as the desired characteristics are obtained. Typical examples of such material include a metal oxide and a metal fluoride. A specific example of the metal oxide is silicon oxide (SiO₂). Specific examples of the metal fluoride include magnesium fluoride and silicon oxide fluoride. Magnesium fluoride or silicon oxide fluoride is preferred from the viewpoint of its refractive index, silicon oxide is preferred from the viewpoints of ease of production, mechanical strength, moisture resistance, and the like, and silicon oxide is preferred in total consideration of various characteristics.

B. Method of Producing Anti-Reflection Film

Hereinafter, an example of a method of producing an anti-reflection film of the present invention is described.

B-1. Preparation of Substrate

First, the substrate 10 is prepared. A resin film formed of a composition containing such resin as described in the section A-1 may be used as the substrate 10, or a commercially available resin film may be used. Any appropriate method can be adopted as a method of forming the resin film. Specific examples thereof include extrusion and a solution casting method. When a laminate of resin films is used as the substrate, the substrate can be formed by, for example, co-extrusion.

When the substrate includes a hard coat layer, the hard coat layer is formed on, for example, the resin film. Any appropriate method can be adopted as a method of forming the hard coat layer on the substrate. Specific examples thereof include: application methods such as roll coating, die coating, air knife coating, blade coating, spin coating, reverse coating, and gravure coating; and printing methods such as gravure printing, screen printing, offset printing, and ink jet printing. When the substrate is constituted of the hard coat layer alone, it is appropriate to peel the resin film from the formed laminate of the resin film/the hard coat layer.

B-2. Formation of Medium-Refractive Index Layer

Next, the medium-refractive index layer 20 is formed on the substrate 10 prepared as described in the section B-1. More specifically, a composition for forming a medium-refractive index layer containing such binder resin and inorganic fine particles as described in the section A-2 (application liquid) is applied onto the substrate. A solvent can be used for improving the applicability of the application liquid. Any appropriate solvent in which the binder resin and the inorganic fine particles can be satisfactorily dispersed can be used as the solvent. Any appropriate method can be adopted as a method for the application. Specific examples of the application method include such methods as described in the section B-1. Next, the applied composition for forming a medium-refractive index layer is cured. When such binder resin as described in the section A-2 is used, the curing is performed by irradiation with an ionizing radiation. When UV light is used as the ionizing radiation, its cumulative light quantity is preferably from 200 mJ to 400 mJ. A heat treatment may be performed before and/or after the irradiation with the ionizing radiation as required. A heating temperature and a heating time can be appropriately set depending on a purpose and the like. As described above, in the production method of the present invention, the medium-refractive index layer 20 is formed by the wet process (application and curing).

B-3. Formation of Adhesion Layer

Next, the adhesion layer 30 is formed on the medium-refractive index layer 20 formed as described in the section B-2 as required. The adhesion layer 30 is typically formed by a dry process. Specific examples of the dry process include a physical vapor deposition (PVD) method and a chemical vapor deposition (CVD) method. Examples of the PVD method include a vacuum deposition method, a reactive deposition method, an ion beam assisted method, a sputtering method, and an ion plating method. An example of the CVD method is a plasma CVD method. Of those, a sputtering method may suitably be used when an in-line treatment is performed. The adhesion layer 30 is formed by, for example, sputtering with silicon. It should be noted that as described above, the adhesion layer is formed as required, and may be omitted.

B-4. Formation of High-Refractive Index Layer

Next, the high-refractive index layer 40 is formed on the medium-refractive index layer 20, or when the adhesion layer 30 is formed, the layer is formed on the adhesion layer. The high-refractive index layer 40 is typically formed by the dry process. In one embodiment, the high-refractive index layer 40 is formed by the sputtering of a metal oxide (such as Nb₂O₅) or a metal nitride. In another embodiment, the high-refractive index layer 40 is formed by sputtering a metal while introducing oxygen to oxidize the metal. In the present invention, thickness control is important because the thickness of the high-refractive index layer is extremely small, but such thickness control can be realized by appropriate sputtering.

B-5. Formation of Low-Refractive Index Layer

Finally, the low-refractive index layer 50 is formed on the high-refractive index layer 40 formed as described in the section B-4. In one embodiment, the low-refractive index layer 50 is formed by the dry process, and is formed by, for example, the sputtering of a metal oxide (such as SiO₂). In another embodiment, the low-refractive index layer 50 is formed by the wet process, and is formed by, for example, the application of a low-refractive index material using polysiloxane as a main component. In addition, the low-refractive index layer may be formed by: performing sputtering until part of a desired thickness is achieved; and then performing application until the remainder is achieved.

An antifouling layer may be arranged as a film that is so thin as not to impair the optical characteristics of the anti-reflection film (from about 1 nm to 10 nm) on the low-refractive index layer as required. The antifouling layer may be formed by the dry process or may be formed by the wet process depending on a formation material therefor.

Thus, the anti-reflection film can be produced.

According to the production method of the present invention, the number of layers to be formed by the dry process is substantially at most two, i.e., the high-refractive index layer and the low-refractive index layer (total thickness of the two layers: about 120 nm). Accordingly, the reflection hue of the anti-reflection film can be controlled in a markedly easy manner as compared with a conventional production method. For example, when design corresponding to the construction of the anti-reflection film of the present invention (medium-refractive index layer/high-refractive index layer/low-refractive index layer) is completed by the dry process, the high-refractive index layer and the low-refractive index layer can be used as components instead of the medium-refractive index layer to provide a construction “high-refractive index layer/low-refractive index layer/high-refractive index layer/low-refractive index layer.” In such construction, however, four layers (total thickness of the four layers: about 200 nm) are to be formed by the dry process. According to the design to be completed by the dry process, the reflection hue largely fluctuates every time one layer is formed and every time the thickness of the layer slightly fluctuates. Accordingly, the thickness of each layer needs to be precisely controlled. In addition, the reflection hue complicatedly changes and hence in-line thickness control involves difficulty. Therefore, when the number of layers to be formed by the dry process is reduced, a burden for the thickness control is markedly alleviated and hence the control of the reflection hue becomes markedly easy.

C. Applications of Anti-Reflection Film

The anti-reflection film of the present invention can be suitably utilized for preventing the reflection of ambient light in an image display apparatus such as a CRT, a liquid crystal display apparatus, or a plasma display panel. The anti-reflection film of the present invention may be used as a single optical member or may be provided as a member integrated with any other optical member. For example, the film may be provided as a polarizing plate with an anti-reflection film by being bonded to a polarizing plate. Such polarizing plate with an anti-reflection film can be suitably used as, for example, a viewer-side polarizing plate of a liquid crystal display apparatus.

### EXAMPLES

The present invention is specifically described below by way of Examples, but the present invention is not limited to Examples. Testing and evaluating methods in Examples are as described below. Moreover, unless otherwise specified, “%” in

Examples is a weight-based unit.

(1) Evaluations for Optical Characteristics

In order for a back-surface reflectance to be cut off, a measurement sample was produced by bonding an obtained anti-reflection film to a black acrylic plate (manufactured by Mitsubishi Rayon Co., Ltd., thickness: 2.0 mm) through a pressure-sensitive adhesive. The reflectance of such measurement sample by 5° regular reflection in a visible light region was measured with a spectrophotometer U4100 (manufactured by Hitachi High-Technologies Corporation). A luminous reflectance (Y) and a hue in the L*a*b* colorimetric system under a C light source were calculated and determined from the spectrum of the resultant reflectance.

(2) Scratch Resistance

A sample having a diameter of 11 mm was rubbed with steel wool #0000 under a load of 500 g in a reciprocating manner 10 times. After that, the degree of a scratch was visually judged.

∘: No remarkable scratch is observed.
x: A remarkable scratch is observed.

### Example 1

A triacetylcellulose (TAC) film with a hard coat (refractive index: 1.53) was used as a substrate. Meanwhile, an application liquid (composition for forming a medium-refractive index layer) was prepared by diluting a resin composition (manufactured by JSR Corporation, trade name: “OPSTAR KZ Series”) containing zirconia particles (average particle diameter: 40 nm, refractive index: 2.19) at a content of 62% with respect to its total solid content with MIBK so that the content of the composition became 3%. The application liquid was applied onto the substrate with a bar coater, and was dried at 60° C. for 1 minute. After that, the dried product was irradiated with UV light having a cumulative light quantity of 300 mJ to form a medium-refractive index layer (refractive index: 1.68, thickness: 100 nm). Next, a high-refractive index layer (refractive index: 2.33, thickness: 12 nm) was formed on the medium-refractive index layer by sputtering Nb₂O₅. Further, a low-refractive index layer (refractive index: 1.47, thickness: 110 nm) was formed on the high-refractive index layer by sputtering SiO₂. Thus, an anti-reflection film was produced. The resultant anti-reflection film was subjected to the evaluations (1) and (2). The results are shown in Table 1.

### Examples 2 to 5 and Comparative Examples 1 to 4

Anti-reflection films were produced according to constructions shown in Table 1. The resultant anti-reflection films were subjected to the evaluations (1) and (2). The results are shown in Table 1.

It should be noted that the same substrate was used in Examples and Comparative Examples. The refractive index of the medium-refractive index layer was changed by changing the content of the zirconia particles in the application liquid as shown in Table 1. The refractive index of the high-refractive index layer was changed by sputtering TiO₂ (refractive index: 2.50) instead of Nb₂O₅. The refractive indices of all low-refractive index layers were kept at a constant value by using SiO₂. In addition, the thickness of the medium-refractive index layer was changed by changing the application thickness of the application liquid. The thickness of any other layer was changed by changing a sputtering thickness.

TABLE 1

| | Medium- | | | High- | | Low- | | | | | Mechanical |
|---|---|---|---|---|---|---|---|---|---|---|---|
| | refractive | | | refractive | | refractive | | | Reflection | | characteristic |
| | index layer | | | index layer | | index layer | | Reflectance | hue | | Scratch |
| | ZrO₂ | n_{M} | d_{M} | n_{H} | d_{H} | n_{L} | d_{L} | Y (%) | a* | b* | Resistance |
| Example 1 | 62 | 1.68 | 105 | 2.33 | 12 | 1.47 | 110 | 0.65 | 3.42 | −7.03 | ∘ |
| Example 2 | 67 | 1.71 | 100 | 2.33 | 15 | 1.47 | 108 | 0.40 | 4.25 | −8.78 | ∘ |
| Example 3 | 72 | 1.75 | 100 | 2.33 | 18 | 1.47 | 107 | 0.29 | 3.63 | −8.19 | ∘ |
| Example 4 | 76 | 1.78 | 98 | 2.33 | 19 | 1.47 | 107 | 0.30 | 1.95 | −9.35 | ∘ |
| Example 5 | 72 | 1.75 | 100 | 2.50 | 14 | 1.47 | 108 | 0.25 | 4.86 | −8.69 | ∘ |
| Comparative | 46 | 1.62 | 125 | 2.33 | 10 | 1.47 | 113 | 1.07 | 3.72 | 1.60 | ∘ |
| Example 1 | | | | | | | | | | | |
| Comparative | 79 | 1.80 | 95 | 2.33 | 22 | 1.47 | 105 | 0.19 | 4.59 | −10.04 | x |
| Example 2 | | | | | | | | | | | |
| Comparative | 72 | 1.75 | 100 | 2.33 | 30 | 1.47 | 107 | 0.27 | 28.08 | −46.25 | ∘ |
| Example 3 | | | | | | | | | | | |
| Comparative | 72 | 1.75 | 100 | 2.33 | 8 | 1.47 | 107 | 1.06 | −4.66 | −14.39 | ∘ |
| Example 4 | | | | | | | | | | | |

*ZrO₂: content (%) of ZrO₂ in total solid content

### Examples 6 and 7, and Comparative Examples 5 to 7

Anti-reflection films were produced according to constructions shown in Table 2. The resultant anti-reflection films were subjected to the evaluations (1) and (2). The results are shown in Table 2.

It should be noted that the same substrate was used in Examples and Comparative Examples. The medium-refractive index layer was formed by using a resin composition (manufactured by Toyo Ink Co., Ltd., trade name: “LIODURAS TYT Series”) containing titanium oxide particles, and the refractive index of the medium-refractive index layer was changed by changing the content of the titanium oxide particles in the application liquid. The refractive indices of all high-refractive index layers were kept at a constant value by using Nb₂O₅. The refractive indices of all low-refractive index layers were kept at a constant value by using SiO₂. In addition, the thickness of the medium-refractive index layer was changed by changing the application thickness of the application liquid. The thickness of any other layer was changed by changing a sputtering thickness.

TABLE 2

| | Medium- | | | High- | | Low- | | | | | Mechanical |
|---|---|---|---|---|---|---|---|---|---|---|---|
| | refractive | | | refractive | | refractive | | | Reflection | | characteristic |
| | index layer | | | index layer | | index layer | | Reflectance | hue | | Scratch |
| | TiO₂ | n_{M} | d_{M} | n_{H} | d_{H} | n_{L} | d_{L} | Y (%) | a* | b* | Resistance |
| Example 6 | 54 | 1.75 | 100 | 2.33 | 18 | 1.47 | 107 | 0.29 | 3.63 | −8.19 | ∘ |
| Example 7 | 58 | 1.78 | 98 | 2.33 | 19 | 1.47 | 107 | 0.30 | 1.95 | −9.35 | ∘ |
| Comparative | 62 | 1.80 | 95 | 2.33 | 22 | 1.47 | 105 | 0.19 | 4.59 | −10.04 | x |
| Example 5 | | | | | | | | | | | |
| Comparative | 67 | 1.85 | 94 | 2.33 | 25 | 1.47 | 103 | 0.16 | 3.92 | −8.64 | x |
| Example 6 | | | | | | | | | | | |
| Comparative | 72 | 1.90 | 80 | 2.33 | 28 | 1.47 | 99 | 0.27 | 5.12 | −8.47 | x |
| Example 7 | | | | | | | | | | | |

*TiO₂: content (%) of TiO₂ in total solid content

<Evaluation>

As is apparent from Table 1 and Table 2, according to each of Examples of the present invention, an anti-reflection film having excellent reflection performance (low reflectivity), an excellent reflection hue that was close to neutral, and an excellent mechanical characteristic (scratch resistance) was able to be obtained. Each of the anti-reflection films of Comparative Examples in which the refractive index of the medium-refractive index layer or the thickness of the high-refractive index layer deviated from the range of the present invention could not satisfy all of the characteristics.

### INDUSTRIAL APPLICABILITY

The anti-reflection film of the present invention can be suitably utilized for preventing the reflection of ambient light in an image display apparatus such as a CRT, a liquid crystal display apparatus, or a plasma display panel.

### REFERENCE SIGNS LIST

10 substrate
20 medium-reflective index layer
30 adhesion layer
40 high-reflective index layer
50 low-reflective index layer
100 anti-reflection film

1. An anti-reflection film, comprising:
a substrate; and
a medium-refractive index layer, a high-refractive index layer, and a low-refractive index layer in the stated order from a substrate side,
wherein:
the substrate has a refractive index ranging from 1.45 to 1.65;
the medium-refractive index layer is formed by applying, onto the substrate, a composition for forming a medium-refractive index layer containing a binder resin and inorganic fine particles, and curing the composition, has a refractive index ranging from 1.67 to 1.78, and has a thickness of from 70 nm to 120 nm;
the high-refractive index layer has a refractive index ranging from 2.00 to 2.60, and has a thickness of from 10 nm to 25 nm; and
the low-refractive index layer has a refractive index ranging from 1.35 to 1.55, and has a thickness of from 70 nm to 120 nm.

2. The anti-reflection film according to claim 1, wherein the thickness of the high-refractive index layer is from 10 nm to 20 nm.

3. The anti-reflection film according to claim 1, wherein the high-refractive index layer is formed by sputtering a metal oxide or a metal nitride, or by sputtering a metal while introducing oxygen to oxidize the metal.

4. The anti-reflection film according to claim 1, wherein the binder resin comprises an ionizing radiation-curable resin, and the inorganic fine particles comprise zirconia particles or titanium oxide particles each having a particle diameter of from 1 nm to 100 nm.

5. A method of producing an anti-reflection film, comprising:
applying, onto a substrate, a composition for forming a medium-refractive index layer containing a binder resin and inorganic fine particles, followed by curing of the composition to form a medium-refractive index layer;
sputtering a metal oxide or a metal nitride onto the medium-refractive index layer, or sputtering a metal onto the medium-refractive index layer while introducing oxygen to oxidize the metal, to form a high-refractive index layer; and
sputtering a metal oxide or a metal fluoride onto the high-refractive index layer to form a low-refractive index layer,
the substrate having a refractive index ranging from 1.45 to 1.65;
the medium-refractive index layer having a refractive index ranging from 1.67 to 1.78, and having a thickness of from 70 nm to 120 nm,
the high-refractive index layer having a refractive index ranging from 2.00 to 2.60, and having a thickness of from 10 nm to 25 nm,
the low-refractive index layer having a refractive index ranging from 1.35 to 1.55, and having a thickness of from 70 nm to 120 nm.

6. A polarizing plate with an anti-reflection film, comprising the anti-reflection film of claim 1.

7. An image display apparatus, comprising the anti-reflection film of claim 1.

8. An image display apparatus, comprising the polarizing plate with an anti-reflection film of claim 6.
